(19) United States
(12) Patent Application Publication
(10) Pub. No.: US 2016/0380178 A1
(43) Pub. Date: Dec. 29, 2016

(54) VIBRATION ACTUATOR

(71) Applicant: NAMIKI SEIMITSU HOUSEKI KABUSHIKI KAISHA, Tokyo (JP)

(72) Inventors: Norikazu SATO, Kuroishi-shi (JP); Tomoyuki KUGOU, Kuroishi-shi (JP); Takayuki KOSHIKAWA, Kuroishi-shi (JP); Chihiro OKAMOTO, Kuroishi-shi (JP); Hiroshi YAMAZAKI, Kuroishi-shi (JP); Eri FUKUSHIMA, Kuroishi-shi (JP); Takafumi ASADA, Kuroishi-shi (JP)

(73) Assignee: NAMIKI SEIMITSU HOUSEKI KABUSHIKI KAISHA, Tokyo (JP)

(21) Appl. No.: 14/373,009

(22) PCT Filed: Feb. 20, 2014
(86) PCT No.: PCT/JP2014/053969

§ 371 Date: Sep. 15, 2016

(30) Foreign Application Priority Data
Nov. 26, 2013 (JP) 2013-244213

(51) Int. Cl. H01L 41/09; H01L 41/047

(52) U.S. Cl. CPC H01L 41/09; H01L 41/047

(57) ABSTRACT

To provide a vibration actuator capable of both rotation and linear drive and providing a stable driving force.

A vibration actuator whose output shaft is moved by vibration includes an oscillatable element with an approximately polygonal shape, the oscillatable element including a hole through which the output shaft is inserted and a slit portion expanding radially from this hole. This slit portion generates the spring force between the output shaft and the oscillatable element to energize the output shaft and holds the output shaft. At least one surface of outer peripheral surfaces of the oscillatable element and its opposite surface are provided with vibrators with the patterned electrodes. A progressive wave is generated in the oscillatable element by applying sequentially voltage to an electrode pattern of the patterned electrodes, thereby rotating the output shaft and displacing the output shaft axially due to the vibration.

### TECHNICAL FIELD

The present invention relates to a vibration actuator that causes rotation or linear movement by the application of a vibration wave to an output shaft with the vibration of a vibrator (including a piezoelectric element or an electrostrictive element).

### BACKGROUND ART

Medical appliances have progressed rapidly and endoscopic devices based on an image diagnostic technique (optical imaging technique) have been widely researched and utilized. As a method of the image diagnosis, the general camera observation and ultrasonic diagnostic devices have been recently replaced by endoscopic devices from which a three-dimensional tomographic image can be obtained by OCT (optical coherence tomography) by the use of the coherence of light capable of photographing a microscopic tomographic image or three-dimensional tomographic image. As a drive source of the device necessary for performing the three-dimensional scanning, a vibration actuator formed by a piezoelectric element or an electrostrictive element having a small diameter but providing a high driving force is expected among various kinds of driving principles including an electromagnetic motor, a piezoelectric motor, and a shape memory alloy type, etc.

For example, Patent Literature 1 has disclosed a linear motor system (100) in which a threaded shaft (120) is inserted slidably into an element (110) with a threaded passage, a clearance (697b) is provided between the element (110) and the threaded shaft (120), and the threaded shaft (120) is rotated and at the same time, moved in parallel axially when rotational vibration is applied to the element (110) by sequentially applying voltage to piezoelectric elements (132a to 132d) attached to four surfaces of the element (110).

In the linear motor system described in Patent Literature 1, however, the threaded shaft is slidably combined with and is in contact with the element with a threaded passage and a clearance is provided between the element and the threaded shaft; therefore, the efficiency of the vibration transmission is low and a sufficient driving force cannot be obtained. Moreover, when the element is inserted into and fixed to a tube of an endoscope or the like, the vibration is absorbed by the tube, whereby the sufficient driving force cannot be applied to the threaded shaft.

Patent Literature 2 has disclosed an ultrasonic linear motor in which piezoelectric elements (2, 3, 4, 5) are attached directly to a square tubular elastic body 1, a driving element (7) is pressed by a plate spring (8) on an inner peripheral surface of the square tubular elastic body (1), and the shaft and the driving element are displaced axially when voltage is applied to the piezoelectric elements (2, 3, 4, 5) to vibrate the square tubular elastic body.

In the ultrasonic linear motor described in Patent Literature 2, however, the square tubular elastic body is stimulated by the piezoelectric elements. When this ultrasonic linear motor is inserted into and fixed to a tube of an endoscope or the like, however, the vibration is absorbed by the tube and the sufficient driving force cannot be applied to the shaft.

Patent Literature 3 has disclosed an ultrasonic scanning device in which an axial operating element (12) is inserted into a hole of a prism-like stator (11), and the axial operating element is rotated or moved axially when voltage is sequentially applied to a plurality of piezoelectric elements (13) attached to the stator (11) to generate a vibration wave.

In the ultrasonic scanning device described in Patent Literature 3, however, if a gap is formed when the axial operating element (12) is inserted into the hole of the stator (11), the vibration wave of the stator does not transmit to the operating element, resulting in that the operation fails. On the other hand, if the insertion has succeeded without the generation of the gap, the friction force is too large to operate the operating element. When the operating element is inserted into and fixed to a tube of an endoscope or the like, the vibration of the stator is absorbed by the tube and the sufficient driving force cannot be applied to the operating element.

### CITATION LIST

### Patent Literature

Patent Literature 1: US 2010/0039715 A1

Patent Literature 2: JP 3213568 B1

Patent Literature 3: WO 2008/038817 A1

### DISCLOSURE OF THE INVENTION

Problems to be Solved by the Invention

The present invention has been made in view of the above circumstances, and an object is to provide a vibration actuator that is small, has a sufficient driving force, and has a stable performance with the vibration wave neither absorbed nor interrupted when the actuator is incorporated in a tube of an endoscope or the like.

### Solutions to the Problems

One means for achieving the above object is a vibration actuator whose output shaft is moved by vibration, wherein a hole is provided approximately on a central axis of an oscillatable element with an approximately polygonal prism shape, a slit portion expanding radially for generating a spring force is provided in the hole, and the output shaft is inserted through the hole. First and second vibrators with patterned electrodes are attached to one surface of the outer periphery of the oscillatable element that is parallel to the output shaft of the oscillatable element and to its opposite surface, and a progressive wave is generated in the oscillatable element by applying sequentially voltage to the electrode pattern of the patterned electrodes, thereby rotating the output shaft and displacing the output shaft axially.

### Effects of the Invention

According to the present invention, a compact vibration actuator capable of both linear movement and rotation operations can be obtained and the vibration is not interrupted even when the actuator is incorporated in a cylindrical tube for an endoscope or the like; therefore, stable output can be obtained.

### BRIEF DESCRIPTION OF THE DRAWINGS

FIG. 1 is a perspective view of a vibration actuator according to a first embodiment of the present invention.

FIG. 2 is a perspective view of a vibration actuator according to a second embodiment of the present invention.

FIG. 3 is a perspective view of a vibration actuator according to a third embodiment of the present invention.

FIG. 4 is a diagram for describing the operation of the vibration actuator.

FIG. 5 is a sectional view of an optical imaging probe in an application example of the present invention.

FIG. 6 is a diagram for describing the scanning range of the optical imaging probe.

FIG. 7 is a timing chart of the operation of the optical imaging probe.

### DESCRIPTION OF PREFERRED EMBODIMENTS

In a first aspect of a vibration actuator according to an embodiment, an oscillatable element with a shape like an approximately polygonal prism has a hole approximately on a central axis thereof, the hole has a slit portion expanding radially, the hole has the output shaft inserted therethrough, a first vibrator is attached to at least one surface of outer peripheral surfaces of the oscillatable element, which is parallel to the output shaft, a second vibrator is attached to the surface opposite to the surface to which the first vibrator is attached, each of the first vibrator and the second vibrator has patterned electrodes, and a progressive wave is generated in the oscillatable element by applying sequentially voltage to an electrode pattern of the patterned electrodes, thereby rotating the output shaft and displacing the output shaft axially. With this structure, the vibration actuator can be obtained in which the progressive wave generated in the oscillatable element applies the rotation and the linear movement to the output shaft to enable the rotation and the linear movement and the stable force is generated.

In a second aspect, a third vibrator with patterned electrodes is attached to a side surface of the oscillatable element that has the hole, and a progressive wave is generated in the oscillatable element by applying sequentially voltage to the electrode pattern of the patterned electrodes of the first vibrator, the second vibrator, and the third vibrator, thereby rotating the output shaft and displacing the output shaft axially. With this structure, a large progressive wave can be generated by the compact oscillatable element and the stable rotation and linear movement can be applied to the output shaft.

In a third aspect, the vibrator is a piezoelectric element or an electrostrictive element. With this structure, a large progressive wave can be generated by the compact oscillatable element according to piezoelectric effect or electrostrictive effect, and the stable rotation and linear movement can he applied to the output shaft with the larger force.

Preferred embodiments of the present invention are described next with reference to the drawings.

### First Embodiment

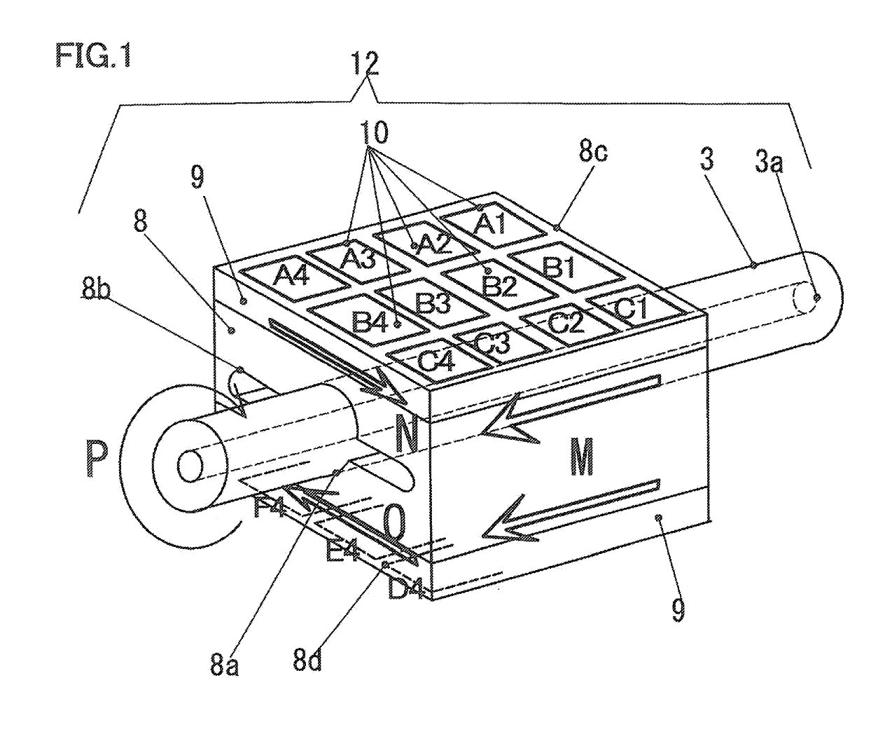

A structure of a vibration actuator according to a first embodiment of the present invention is described with reference to FIG. 1. FIG. 1 is a perspective view of a vibration actuator according to the embodiment of the present invention. An oscillatable element 8 with a shape like an approximately polygonal prism (a quadrangular prism in FIG. 1) has a sliding hole 8a that penetrates approximately on a central axis thereof, and this sliding hole 8a has a slit portion 8b expanding radially. This sliding hole 8a has an output shaft 3 inserted therethrough, and the oscillatable element 8 has first and second piezoelectric elements 9 with patterned electrodes 10 attached to at least one surface 8c on the outer periphery thereof in parallel to the output shaft 3 and a surface 8d opposite to the surface 8c. Each piezoelectric element 9 is provided with the patterned electrodes 10 using noble metal by a sputtering method or by a printing method of conductive ink.

The outer peripheral surface 8c has N electrodes A1 to An and N electrodes B1 to Bn arranged thereon axially. Preferably, N electrodes C1 to Cn are additionally provided similarly axially. The outer peripheral surface 8d on the opposite side has N electrodes D1 to Dn and N electrodes E1 to En arranged thereon. Preferably, N electrodes F1 to Fn are additionally provided similarly axially.

The slit portion 8b is provided approximately radially from the output shaft 3 at one position or a plurality of positions (two positions in FIG. 1), and causes the oscillatable element 8 to have the spring property, whereby the stable friction force (for example, approximately 1 Newton) is generated between the output shaft 3 and the sliding hole 8a.

Preferably, a hole 3a is formed approximately at the center of the output shaft 3, and an optical fiber or an operation wire for an endoscope is inserted into the hole 3a as necessary.

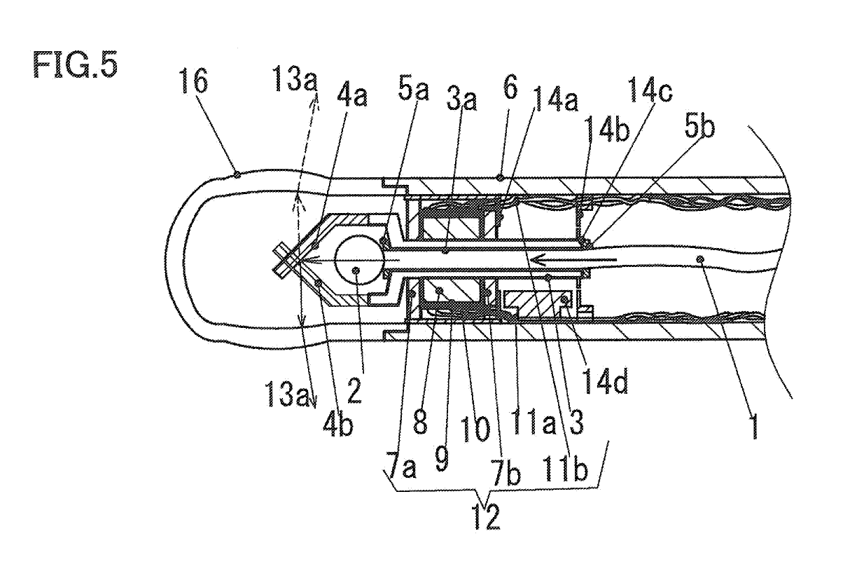

The operation of the vibration actuator of FIG. 1 is described. An approximately sinusoidal voltage is sequentially applied to the patterned electrodes 10 of FIG. 1 through electric wires 11a and 11b of FIG. 5, and by changing the order of the application, the output shaft 3 can be operated in the linear direction (arrow M in the drawing) or the rotation direction (arrow P in the drawing).

In order to operate the output shaft 3 in the linear direction along the arrow M in FIG. 1, the voltage is applied firstly to the xix electrodes A1, B1, C1, D1 (not illustrated) located opposite to C1, E1 (not illustrated) located opposite to B1, and F1 (not illustrated) located opposite to A1.

Next, the voltage is applied secondly to the six electrodes A2, B2, C2, D2 (not illustrated) located opposite to C2, E2 (not illustrated) located opposite to B2, and F2 (not illustrated) located opposite to A2.

Next, the voltage is applied thirdly to the six electrodes A3, B3, C3, D3 (not illustrated) located opposite to C3, E3 (not illustrated) located opposite to B3, and F3 (not illustrated) located opposite to A3.

Next, the voltage is applied fourthly to the six electrodes A4, B4, C4, D4, E4, and F4. After that, the voltage is applied again to the six electrodes A1, B1, C1, D1, E1 and F1 to which the voltage is applied first; this is repeated. Thus, the output shaft 3 slides in the direction of the arrow M.

When the voltage application is repeated reversely, the output shaft 3 slides in the direction opposite to the direction of the arrow M in FIG. 1.

Next, for rotating the output shaft 3, the voltage is applied firstly to the eight electrodes A1 to A4 and D1 to D4, secondly to the eight electrodes B1 to B4 and E1 to E4, thirdly to the eight electrodes C1 to C4 and F1 to F4, and next to the eight electrodes again to which the voltage is applied first; this is repeated. This produces the progressive waves in the oscillatable element 8 along the arrow N and the arrow O in the drawing, thereby rotating the output shaft 3 in the direction of the arrow P.

When the voltage application is repeated reversely, the output shaft 3 is rotated in the direction opposite to the arrow P in FIG. 1.

Since a vibration actuator 12 of the present invention has a simple structure, the thickness and volume of the piezoelectric element 9 can be set considerably large relative to the weight and volume of the oscillatable element 8 and the output shaft can generate higher power. In this embodiment, when the thickness of the piezoelectric element 9 is t1 and the thickness of the thinnest part of the oscillatable element 8 near the output shaft 3 is t2 in FIG. 1, the highest power can be obtained when t1≧t2 is satisfied.

Since the provision of the slit portion 8b for the oscillatable element 8 generates the spring force and presses the output shaft 3 with the stable force, the power generated by the output shaft 3 changes less and is stably high.

FIG. 5 to FIG. 7 illustrate the application example of the vibration actuator according to the first embodiment of the present invention, which are the diagrams illustrating an optical imaging probe of an OCT endoscope device.

In FIG. 5, the output shaft 3 is supported rotatably and slidably by two bearings 7a and 7b. The vibration actuator 12 is fixed in a tube 6 in a manner that the actuator is weakly supported by a flat spring or soft rubber or the like as necessary so that the vibration of the vibration actuator 12 is not interrupted.

For example, a near-infrared ray emitted from an endoscope device main body (not illustrated) is guided to an optical fiber 1 illustrated in FIG. 5, and delivered forward through a condensing lens 2, and then the radiation angle thereof is changed by an optical path changing unit 4a into an approximately perpendicular direction. Since the optical path changing unit 4 is rotated by the vibration actuator 12, the ray is emitted in the 360°-whole circumferential direction including the direction of 13a in the drawing. The ray transmits through a light transmission portion 16, is delivered to a subject such as the affected part of a human body, and the reflection light from the subject returns to the endoscope device main body through the optical path changing unit 4, the condensing lens 2, and the optical fiber 1 in a direction opposite to the direction to which the ray has been guided. This enables the two-dimensional image along the 360°-whole circumference to be captured. Note that the capture of the three-dimensional image is then started by sequentially operating the vibration actuator 12 in the following manner.

When the output shaft 3 of the vibration actuator 12 of FIG. 5 is linearly moved, the output shaft 3 pushes or pulls the optical fiber 1 in the tube 6 and at the same time displaces the condensing lens 2, the optical path changing unit 4, and the optical fiber 1 near the end axially and integrally, thereby also displacing the radiation of the ray axially. Thus, the three-dimensional image data are accumulated in the endoscope device main body.

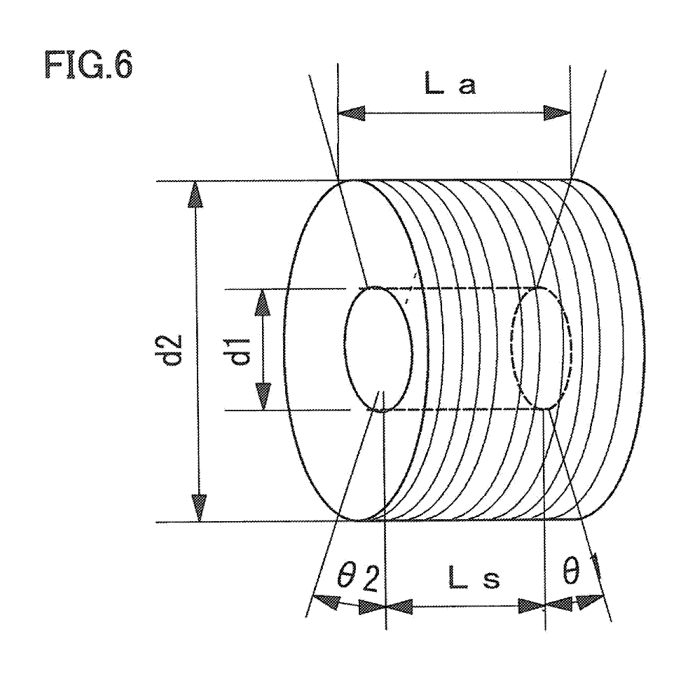

FIG. 6 illustrates the range of the ray emitted from the optical path changing unit 4. in the drawing, d2 represents the range where the near-infrared ray transmits, which has a diameter of approximately 4 to 20 mm, and d1 represents the outer diameter of the tube 6, which is approximately 2 mm. in the drawing, Ls represents the travel distance of the output shaft 3, which is approximately 2 to 10 mm. Since the ray 13a in FIG. 1 is refracted slightly by the light transmission portion 16 to radiate widely at angles of θ1 and θ2, the three-dimensional observation with the OCT endoscope is conducted axially in the range represented by La in FIG. 6.

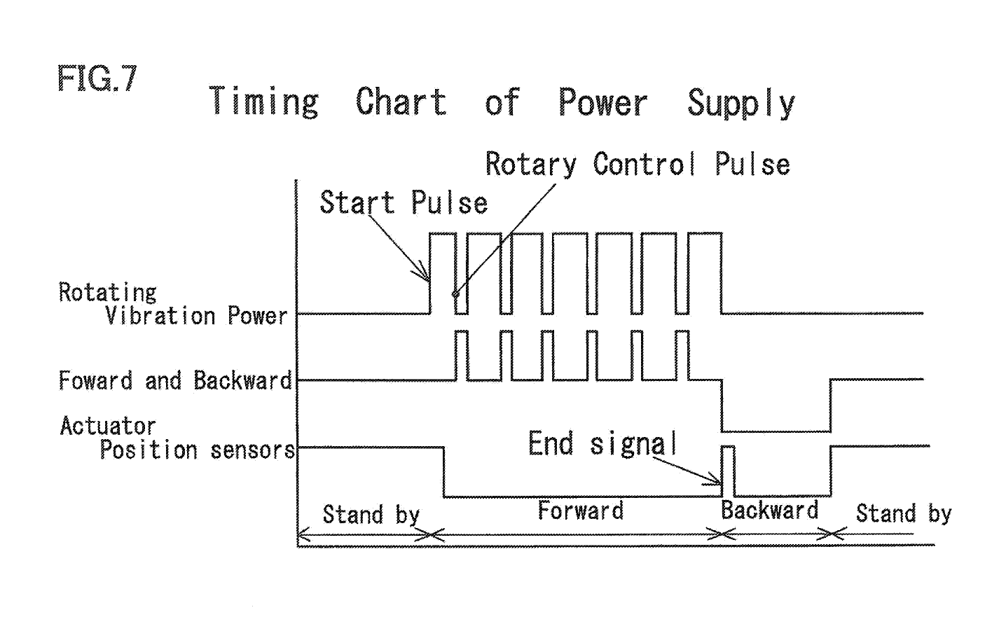

FIG. 7 is a timing chart of the optical imaging probe in the present invention. The top waveform represents the ON-OFF state as to whether the voltage is applied to the patterned electrodes 10 in the direction where the output shaft 3 rotates. The middle waveform represents the ON-OFF state as to whether the voltage is applied in the direction where the output shaft 3 linearly moves, in which the displacement in the positive direction is represented by plus while the displacement in the negative direction is represented by minus. The bottom waveform represents the output waveform of fixed side sensors 14a and 14b illustrated in FIG. 5 for detecting the start and end positions of the vibration actuator 12 axially.

Upon the operation of the switch by a user (doctor, etc.) of the endoscope device, the endoscope device generates a start pulse. In the timing chart of FIG. 7, firstly, the output shaft 3 starts to rotate at low speed of approximately 60 to 120 [rotations/min] in a direction indicated by the arrow P of FIG. 1; secondly, the electric conduction is stopped once when one pulse is output from a rotation detection sensor 14d before the output shaft 3 rotates once, thereby stopping the rotation of the vibration actuator; and thirdly, the output shaft 3 slides in the positive direction within a certain period (for example, 0.01 [seconds]) and on this occasion, the output shaft moves by approximately 20 μm.

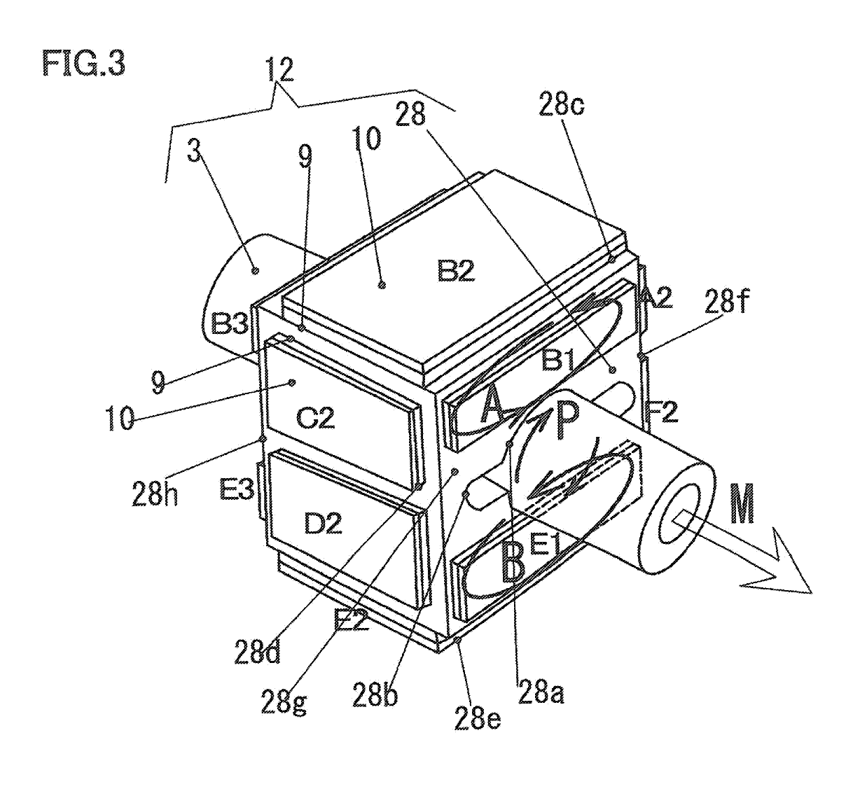

Next, the output shaft 3 rotates again at a speed of approximately 60 to 120 [rotations/min] in the direction indicated by the arrow P in FIG. 3, and thus, the first, second and third operations are repeated in this order.

After having moved to the terminal, fourthly, the output shaft generates the output by the approach of a moving side sensor 14c to the fixed side sensor 14a. Upon the detection of this terminal signal, the output shaft 3 stops.

Fifthly, the output shaft 3 moves backward at high speed and sixthly, upon the detection of the output of the start position from the fixed side sensor 14b, the backward movement is ended and the electric conduction is stopped, thereby stopping both the rotation and the linear movement of the output shaft. The stop position of the output shaft 3 on this occasion corresponds to the standby position, where the next start pulse is awaited.

Thus, the ray radiation direction of the optical imaging probe including the vibration actuator can be changed to the rotation and linear directions and the probe can perform three-dimensional scanning, and moreover the probe can receive the near-infrared ray reflected from, for example, the affected part of a human body According to the structure of the present invention, there is no unevenness in rotation speed of the optical path changing unit 4 and the vibration actuator 12 incorporated in the vicinity of the end of the tube 6, and the optical path changing unit 4 accurately scans the light incident into the end after being reflected on the subject such as a human body and guides the light to the optical fiber 1 on the rear side; thus, the spatial resolution as high as 10 μm can be obtained.

### Second Embodiment

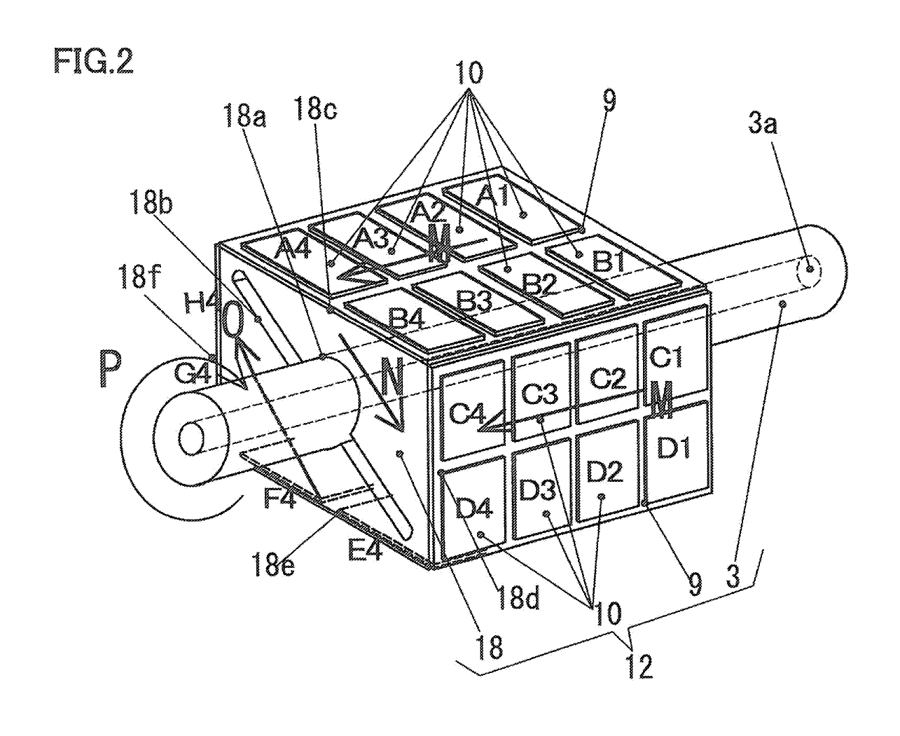

Next, a structure of a vibration actuator according to a second embodiment of the present invention is described with reference to FIG. 2. FIG. 2 is a perspective view of the vibration actuator according to the second embodiment of the present invention.

An oscillatable element 18 with a shape like an approximately polygonal prism has a sliding hole 18a that penetrates approximately on a central axis thereof, and this sliding hole 18a has a slit portion 18b expanding radially. This sliding hole 18a has the output shaft 3 inserted therethrough or lightly force-fitted thereinto. The oscillatable element 18 has outer peripheral surfaces 18c, 18d, 18e, and 18f in parallel to the output shaft 3, to each of which the piezoelectric element 9 with the patterned electrodes 10 is attached. Each piezoelectric element 9 is provided with the patterned electrodes 10 in the grid shape, for example.

A surface of the piezoelectric element 9 attached to the outer peripheral surface 18c of the oscillatable element 18 has N electrodes A1 to An and N electrodes B1 to Bn attached thereto axially. The adjacent outer peripheral surface 18d is provided with N electrodes C1 to Cn and N electrodes D1 to Dn. The outer peripheral surface 18e has the piezoelectric element 9 with the electrodes E1 to En and F1 to Fn attached thereto and the outer peripheral surface 18f has the piezoelectric element 9 with the electrodes G1 to Gn and H1 to Hn attached thereto.

The slit portion 18b is provided for at least one position (two positions in FIG. 2) approximately radially from the output shaft 3 and causes the oscillatable element 18 to have the spring property, whereby the stable friction force is generated between the output shaft 3 and the sliding hole 8a.

Description is hereinafter made of the rotation and linear operations of the vibration actuator 12.

The voltage generated in the approximately sinusoidal form is applied sequentially to the patterned electrodes 10. By changing the order of the application, the output shaft 3 can operate in the linear direction (direction indicated by the arrow M and its opposite direction in the drawing) or the rotating direction (direction indicated by the arrow P and its opposite direction in the drawing).

In order to move the output shaft 3 linearly in the direction of M in FIG. 2, the voltage is applied firstly to the four electrodes A1, B1, C1, and D1, secondly to the four electrodes A2, B2, C2, and D2, thirdly to the four electrodes A3, B3, C3, and D3, and fourthly to the four electrodes A4, B4, C4, and D4. After that, the voltage is applied to the four electrodes A1, B1, C1, and D1 again to which the voltage is applied first; this is repeated. This produces the progressive wave in the oscillatable element 18 linearly along the arrow M and this progressive wave causes the output shaft 3 to slide in the direction of the arrow M.

Next, the direction where the voltage is applied repeatedly is reversed; specifically, the direction is set in the order of the fourth, third, second, first and fourth. Then, the output shaft 3 slides in the direction opposite to the arrow M in FIG. 2.

Next, in the case of rotating the output shaft 3, the voltage is applied firstly to the eight electrodes A1 to A4 and E1 to E4, secondly to the eight electrodes B1 to B4 and F1 to F4, thirdly to the eight electrodes C1 to C4 and G1 to G4, and fourthly to the eight electrodes D1 to D4 and H1 to H4. After that, the voltage is applied again the eight electrodes A1 to A4 and E1 to E4 to which the voltage is applied first; this is repeated. This produces the progressive waves in the oscillatable element 18 along the arrow N and the arrow O in the drawing, thereby rotating the output shaft 3 in the direction of arrow P with these two progressive waves.

When the direction to which the voltage is applied repeatedly is reversed, the output shaft 3 is rotated in the direction opposite to the arrow P in FIG. 2.

In the second embodiment, the piezoelectric elements 9 are attached to the entire surfaces on the outer periphery of the oscillatable element 18; therefore, a strong progressive wave can be generated from a number of piezoelectric elements. However, since it is difficult to attach the thick piezoelectric elements due to its structure as compared with the first embodiment illustrated in FIG. 1, the high operation force is generated by attaching a number of thin piezoelectric elements instead.

Note that the force of the progressive wave generated from the piezoelectric elements 9 is in proportion to the area or the number of the attached piezoelectric elements 9 and also to the thickness of the piezoelectric element 9. The shape and size of the piezoelectric element 9 and the patterned electrode 10 are designed in consideration of this principle. However, when the thickness of the piezoelectric element 9 is increased, the voltage to be applied needs to be increased in proportion to the thickness therefore, there is limitation on the thickness and area of the piezoelectric element 9.

According to the present invention, the compact vibration actuator that can apply the rotation and the linear movement to the output shaft alone can be obtained and the stable driving force can be generated.

### Third Embodiment

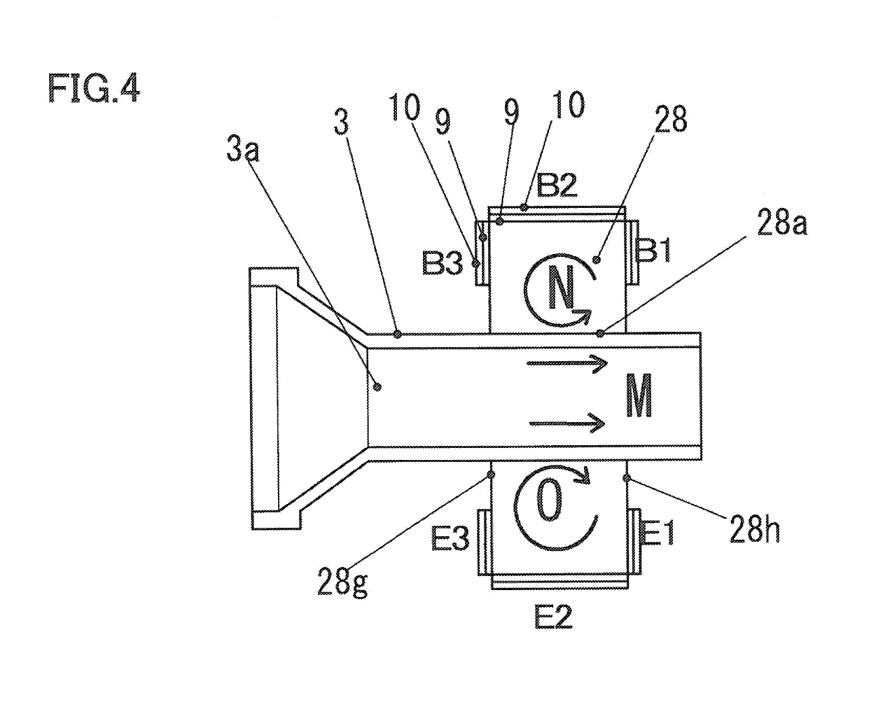

Next, a structure of a vibration actuator according to a third embodiment of the present invention is described with reference to FIG. 3 and FIG. 4. FIG. 3 is a perspective view of the vibration actuator according to the third embodiment of the present invention.

An oscillatable element 28 with a shape like an approximately polygonal prism has a sliding hole 28a that penetrates approximately on a central axis thereof, and this sliding hole 28a has a slit portion 28b expanding radially This sliding hole 28a has the output shaft 3 inserted therethrough or lightly force-fitted thereinto. The slit portion 28b causes the oscillatable element 28 to have the spring property, whereby the stable friction force is generated between the output shaft 3 and the sliding hole 28a.

Each of outer peripheral surfaces 28c, 28d, 28e, and 28f of the oscillatable element 28 that is in parallel to the output shaft 3 has the piezoelectric element 9 with the patterned electrodes 10 attached thereto. Moreover, two side surfaces 28g and 28b having the sliding hole 28a each have the piezoelectric element 9 with the patterned electrodes 10 attached thereto.

The surface of the piezoelectric element 9 on the outer peripheral surface 28c of the oscillatable element 28 is provided with the electrode denoted by the reference symbol B2 in the drawing, the surface of the piezoelectric element 9 on the outer peripheral surface 28d of the piezoelectric element 9 is provided with the electrodes C2 and D1 the surface of the piezoelectric element 9 on the outer peripheral surface 28e of the oscillatable element 28 is provided with the electrode denoted by the reference symbol E2, and the surface of the piezoelectric element 9 on the outer peripheral surface 28f of the oscillatable element 28 is provided with the electrodes F2 and A2. The surface of the piezoelectric element 9 on the side surface 28g is provided with the electrodes B1 and E1, and the surface of the piezoelectric element 9 on the side surface 28h is provided with the electrodes B3 and E3, and all of these electrodes constitute a set of electrode patterns.

Description is hereinafter made of the rotation and the linear operation of the vibration actuator 12. The voltage generated in the approximately sinusoidal form is applied sequentially to the patterned electrodes 10. By changing the order of the application, the output shaft 3 can be operated in the linear direction (direction indicated by the arrow M and its opposite direction in the drawing) or the rotating direction (direction indicated by the arrow P and its opposite direction in the drawing).

In the case of moving the output shaft 3 in the direction of the arrow M in FIG. 3 and FIG. 4, the voltage is applied firstly to the two electrodes B1 and E1, secondly to the two electrodes B2 and E2, and thirdly to the two electrodes B3 and E3. After that, the voltage is applied again to the two electrodes B1 and E1, to which the voltage is applied first, and this is repeated. This produces the rotation progressive waves in the oscillatable element 28 in the directions of the arrow N and the arrow O and these two rotation progressive waves cause the output shaft 3 to move linearly in the direction of the arrow M.

Next, the direction where the voltage is applied repeatedly is reversed; specifically, the direction is set in the order of the third, second, first and third. Thus, the output shaft 3 is moved linearly in the direction opposite to the direction of the arrow M in FIG. 4.

Next, in the case of rotating the output shaft 3, the voltage is applied firstly to the two electrodes A2 and D2, secondly to the two electrodes B2 and E2, thirdly to the two electrodes C2 and F2, and next to the two electrodes A2 and D2 again to which the voltage is applied first. This produces the progressive waves in the oscillatable element 28 along the arrow A and the arrow B in the drawing, thereby rotating the output shaft 3 in the direction of arrow P with these progressive waves.

When the direction to which the voltage is applied repeatedly is reversed, the output shaft 3 is rotated in the direction opposite to the arrow P in FIG. 4.

In the third embodiment, the piezoelectric elements 9 are attached to the entire outer peripheral surfaces and side surfaces of the oscillatable element 28, whereby a strong progressive wave can be generated from a number of piezoelectric elements.

According to the present invention, the compact actuator that can apply the rotation and the linear movement to the output shaft alone can be obtained. Moreover the vibration transmission efficiency is high and the vibration is not interrupted even when the actuator is incorporated in a cylindrical tube for the endoscope or the like, whereby the stable output can be obtained.

The diameter of the hole 3a of the output shaft 3 is 0.2 to 0.5 mm, which is sufficiently larger than the diameter of the optical fiber 1; therefore, the optical fiber 1 is not brought into contact with the hole 3a. Even if the optical fiber 1 is slightly brought into contact with the hole 3a, the abrasion powder is not generated. Further, the variation in rotary friction torque does not occur.

Note that the output shaft 3 illustrated in FIG. 1 is formed of a metal or ceramic material, and is formed by drawing molten metal with a mold, or extruding an unburned ceramic material with a mold into a hollow shape and curing and then grinding the material, for example.

The oscillatable element 8 preferably has the spring property, and the difference in linear expansion coefficient between the oscillatable element 8 and the piezoelectric element 9 is preferably small; therefore, the oscillatable element 8 is formed of stainless steel or zirconia ceramics, for example.

Note that the oscillatable element 8 having the slit portion 8b does not necessarily have the integrated structure but may be formed by stacking a number of thin steel plates, for example.

According to the present invention, the rotation and the linear movement are conducted by one vibration actuator; therefore, the actuator is compact and can generate the stable power. Moreover, since the optical fiber does not rotate relatively in the catheter of the endoscope device or the like, the rubbing does not occur and moreover, neither the rotation transmission delay nor the variation in torque does not occur. Thus, a favorable three-dimensional image of the endoscope can be obtained.

### INDUSTRIAL APPLICABILITY

In the use for the optical imaging probe of the three-dimensional scanning type, for example, which is employed for the OCT type endoscope system that has recently advanced rapidly, the vibration actuator of the present invention is compact and can provide the sufficient operation force in the rotation and the linear movement. In particular, since the vibration is not absorbed or interrupted even when the actuator is incorporated in the tube of the endoscope or the like, the stable performance can be provided. Furthermore, besides the use in the endoscope, the actuator can be incorporated in a hand of an industrial microrobot or the like, in which case the driving force can be increased in a smaller size.

### DESCRIPTION OF REFERENCE SIGNS

1 optical fiber
2 condensing lens
3 output shaft
3a hole
4a, 4b, 4c, 4d optical path changing unit
5a, 5b optical fiber clamp
6 tube (catheter)
7a, 7b bearing
8, 18 oscillatable element
8a sliding hole
8b, 18a slit portion
9 piezoelectric element
10 patterned electrode
11a, 11b electric wire
12 actuator
13a, 13b ray
14a, 14b fixed side sensor
14c moving side sensor
16 light transmission portion

1. A vibration actuator whose output shaft is moved by vibration, wherein
an oscillatable element with a shape like an approximately polygonal prism has a hole approximately on a central axis thereof,
the hole has a slit portion expanding radially,
the hole has the output shaft inserted therethrough,
a first vibrator is attached to at least one surface of outer peripheral surfaces of the oscillatable element, the one surface being parallel to the output shaft,
a second vibrator is attached to the surface opposite to the surface to which the first vibrator is attached,
each of the first vibrator and the second vibrator has patterned electrodes, and
a progressive wave is generated in the oscillatable element by applying sequentially voltage to an electrode pattern of the patterned electrodes, thereby rotating the output shaft and displacing the output shaft axially.

2. The vibration actuator according to claim 1, wherein
a third vibrator with patterned electrodes is attached to a side surface of the oscillatable element that has the hole, and
a progressive wave is generated in the oscillatable element by applying sequentially voltage to the electrode pattern of the patterned electrodes of the first vibrator, the second vibrator, and the third vibrator, thereby rotating the output shaft and displacing the output shaft axially.

3. The vibration actuator according to claim 1, wherein the vibrator is a piezoelectric element or an electrostrictive element.

4. The vibration actuator according to claim 2, wherein the vibrator is a piezoelectric element or an electrostrictive element.
